(19) United States
(12) Patent Application Publication
(10) Pub. No.: US 2023/0198499 A1
(43) Pub. Date: Jun. 22, 2023

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/110,414

(22) Filed: Feb. 16, 2023

Related U.S. Application Data
(63) Continuation of application No. PCT/JP2021/030877, filed on Aug. 23, 2021.
(60) Provisional application No. 63/069,211, filed on Aug. 24, 2020.

(51) Int. Cl. H03H 9/17; H03H 9/13

(52) U.S. Cl. CPC H03H 9/173; H03H 9/13; H03H 9/02031

(57) ABSTRACT

An acoustic wave device includes a piezoelectric layer and electrodes including at least a pair of electrodes on a first main surface, facing each other in a second direction crossing a first direction, and adjacent to each other. At least three or more of the electrodes are arranged in the second direction. The electrodes include at least two electrodes having different film thicknesses from each other. The electrodes include at least two electrodes having the same or substantially the same film thickness and being adjacent to each other.

### CROSS REFERENCE TO RELATED APPLICATIONS

This application claims the benefit of priority to Provisional Application No. 63/069,211 filed on Aug. 24, 2020 and is a Continuation Application of PCT Application No. PCT/JP2021/030877 filed on Aug. 23, 2021. The entire contents of each application are hereby incorporated herein by reference.

### BACKGROUND OF THE INVENTION

### 1. Field of the Invention

The present disclosure relates to an acoustic wave device including a piezoelectric layer including lithium niobate or lithium tantalate.

### 2. Description of the Related Art

Japanese Unexamined Patent Application Publication No. 2012-257019 describes an acoustic wave device.

In an acoustic wave device, there is a possibility that spurious responses may easily deteriorate the resonance characteristics of the acoustic wave device.

### SUMMARY OF THE INVENTION

Preferred embodiments of the present invention provide acoustic wave devices that each reduce or prevent deterioration of resonance characteristics.

An acoustic wave device according to a preferred embodiment of the present invention includes a piezoelectric layer including a first main surface and a second main surface, the second main surface being opposed to the first main surface and located in a first direction from the first main surface, and a plurality of electrodes including at least a pair of electrodes on the first main surface, facing each other in a second direction crossing the first direction, and adjacent to each other. At least three or more of the plurality of electrodes are arranged in the second direction. The plurality of electrodes include at least two electrodes having different film thicknesses from each other. The plurality of electrodes include at least two electrodes that have the same or substantially the same film thickness and are adjacent to each other.

An acoustic wave device according to a preferred embodiment of the present invention includes a piezoelectric layer including a first main surface and a second main surface, the second main surface being opposed to the first main surface and located in a first direction from the first main surface, and a plurality of electrodes including at least a pair of electrodes on the first main surface, facing each other in a second direction crossing the first direction, and adjacent to each other. At least three or more of the plurality of electrodes are arranged in the second direction. The plurality of electrodes include at least three electrodes having different film thicknesses from one another.

According to preferred embodiments of the present invention, deterioration of resonance characteristics is able to be reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view illustrating an acoustic wave device according to a first preferred embodiment of the present invention.

FIG. 1B is a plan view illustrating an electrode structure according to the first preferred embodiment of the present invention.

FIG. 2 is a sectional view taken along line II-II of FIG. 1A.

FIG. 3A is a schematic sectional view illustrating a Lamb wave propagating in a piezoelectric layer of a comparative example.

FIG. 3B is a schematic sectional view illustrating a bulk wave in a thickness-shear primary mode propagating in a piezoelectric layer according to the first preferred embodiment of the present invention.

FIG. 4 is a schematic sectional view illustrating an amplitude direction of the bulk wave in the thickness-shear primary mode propagating in the piezoelectric layer according to the first preferred embodiment of the present invention.

FIG. 5 is a graph illustrating exemplary resonance characteristics of the acoustic wave device according to the first preferred embodiment of the present invention.

FIG. 6 is a relationship between d/2p and a fractional bandwidth as a resonator, where p is the center-to-center distance between adjacent electrodes in the acoustic wave device of the first preferred embodiment of the present invention or the average distance of the center-to-center distances and d is the average thickness of the piezoelectric layer.

FIG. 7 is a plan view illustrating a case where a pair of electrodes are provided in the acoustic wave device according to the first preferred embodiment of the present invention.

FIG. 8 is a sectional view of a portion of a modification of the first preferred embodiment of the present invention taken along line II-II of FIG. 1A.

FIG. 9 is a sectional view taken along line IX-IX of FIG. 1B in the first preferred embodiment of the present invention.

FIG. 10A is a graph illustrating a relationship between spurious and frequency in the first preferred embodiment of the present invention.

FIG. 10B is a graph illustrating a relationship between spurious and frequency in a comparative example.

FIG. 11 is a sectional view of a portion according to a second preferred embodiment taken along line IX-IX of FIG. 1B.

FIG. 12 is a sectional view of a portion according to a third preferred embodiment of the present invention taken along line IX-IX of FIG. 1B.

FIG. 13 is a sectional view of a portion according to a fourth preferred embodiment of the present invention taken along line IX-IX of FIG. 1B.

FIG. 14 is a sectional view of a portion according to a fifth preferred embodiment of the present invention taken along line IX-IX of FIG. 1B.

FIG. 15 is a sectional view of a portion according to the sixth preferred embodiment of the present invention taken along line IX-IX of FIG. 1B.

### DETAILED DESCRIPTION OF THE PREFERRED EMBODIMENTS

Preferred embodiments of the present invention will be described in detail below with reference to the drawings. The present disclosure is not limited to the preferred embodiments. The preferred embodiments described in the present disclosure are examples. In modifications in which the configurations according to the different preferred embodiments may be partially replaced with one another or may be combined with one another, for the second and subsequent preferred embodiments, descriptions of matters that are common with the first preferred embodiment will be omitted, and only differences will be described. In particular, the same or similar advantageous effects obtained with the same or similar configurations will not be described in every preferred embodiment.

### First Preferred Embodiment

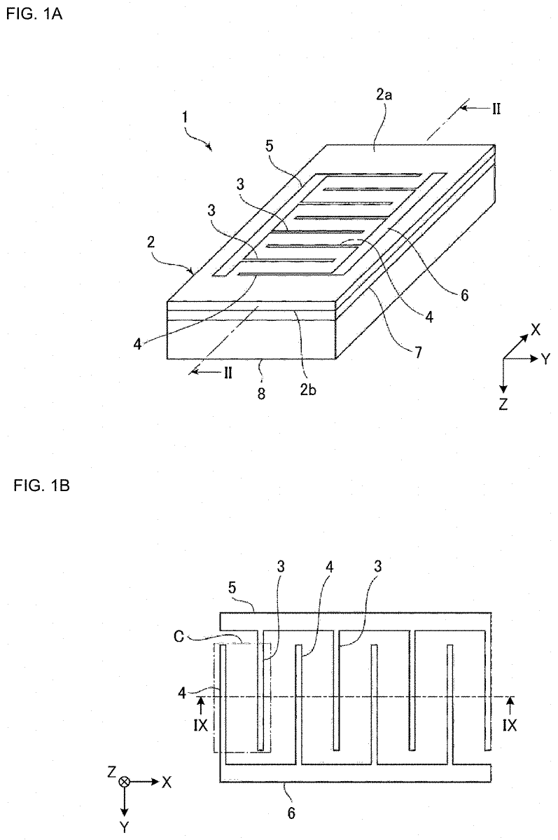

FIG. 1A is a perspective view illustrating an acoustic wave device according to the first preferred embodiment. FIG. 1B is a plan view illustrating an electrode structure according to the first preferred embodiment.

An acoustic wave device 1 according to the first preferred embodiment includes a piezoelectric layer 2 made of, for example, LiNbO₃. The piezoelectric layer 2 may be made of, for example, LiTaO₃. Regarding the cut-angles of LiNbO₃ and LiTaO₃, Z cut is used in the first preferred embodiment. Alternatively, rotated Y-cut or X cut may be used. A propagation direction of, for example, about ±30° in Y propagation and X propagation is preferable.

Although the thickness of the piezoelectric layer 2 is not particularly limited, the thickness of the piezoelectric layer 2 is preferably, for example, about 50 nm or more and about 1,000 nm or less in order to effectively excite a thickness-shear primary mode.

The piezoelectric layer 2 includes a first main surface 2a and a second main surface 2b facing each other in a Z direction. Electrodes 3 and electrodes 4 are arranged on the first main surface 2a.

Here, each of the electrodes 3 is an example of a “first electrode”, and each of the electrodes 4 is an example of a “second electrode”. In FIG. 1A and FIG. 1B, the plurality of electrodes 3 are connected to a first busbar 5. The plurality of electrodes 4 are connected to a second busbar 6. The plurality of electrodes 3 and the plurality of electrodes 4 are interdigitated with one another.

The electrodes 3 and the electrodes 4 each have a rectangular or substantially rectangular shape and each have a length direction. Each of the electrodes 3 and one of the electrodes 4 that is adjacent to the electrode 3 face each other in a direction perpendicular or substantially perpendicular to the length direction. The length direction of the electrodes 3 and 4 and the direction perpendicular or substantially perpendicular to the length direction of the electrodes 3 and 4 both cross the thickness direction of the piezoelectric layer 2. Accordingly, it can also be said that each of the electrodes 3 and the adjacent electrode 4 face each other in a direction crossing the thickness direction of the piezoelectric layer 2. In the following description, the thickness direction of the piezoelectric layer 2 will sometimes be referred to as the Z direction (or a first direction). The direction perpendicular or substantially perpendicular to the length direction of the electrodes 3 and 4 will sometimes be referred to as an X direction (or a second direction). The length direction of the electrodes 3 and 4 will sometimes be referred to as a Y direction (or a third direction).

In addition, the length direction of the electrodes 3 and 4 and a direction perpendicular or substantially perpendicular to the length direction of the electrodes 3 and 4 illustrated in FIGS. 1A and 1B are interchangeable. In other words, in FIGS. 1A and 1B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 1A and 1B. The electrodes 3 are connected to one potential, and the electrodes 4 are connected to another potential. Each of the electrodes 3 is paired with one of the electrodes 4 that is adjacent to the electrode 3, and these pairs of electrodes 3 and 4 are arranged in the direction perpendicular or substantially perpendicular to the length direction of the electrodes 3 and 4.

Here, when one of the electrodes 3 and the corresponding electrode 4 are adjacent to each other, the electrode 3 and the electrode 4 are arranged so as not to be in direct contact with each other, but so as to be spaced apart from each other. In addition, when one of the electrodes 3 and the corresponding electrode 4 are adjacent to each other, electrodes including the other electrodes 3 and 4 that are connected to a hot electrode or a ground electrode are not located between the electrode 3 and the electrode 4. The number of the pairs does not need to be an integer and may be, for example, 1.5, 2.5, or the like.

It is preferable that the center-to-center distance between each pair of the electrodes 3 and 4, that is, the pitch of the electrodes 3 and 4, is, for example, within a range of about 1 μm or more to about 10 μm or less. The center-to-center distance between each pair of the electrodes 3 and 4 corresponds to the distance from the center of the width dimension of the electrode 3 in a direction perpendicular or substantially perpendicular to the length direction of the electrode 3 to the center of the width dimension of the electrode 4 in a direction perpendicular or substantially perpendicular to the length direction of the electrode 4.

In addition, in the case where at least one of the number of the electrodes 3 and the number of the electrodes 4 is two or more (when a single electrode 3 and a single electrode 4 define a pair of electrodes and the number of pairs of electrodes is 1.5 or more), the center-to-center distance between the electrode 3 and the electrode 4 refers to the average value of the center-to-center distances between the adjacent electrodes 3 and 4 included in the 1.5 or more pairs of electrodes.

The width of each of the electrodes 3 and 4, that is, a dimension of each of the electrodes 3 and 4 in the direction in which the electrodes 3 and 4 face one another, is preferably, for example, within a range of about 150 nm or more to about 1,000 nm or less. The center-to-center distance between each pair of the electrodes 3 and 4 corresponds to the distance from the center of a dimension (width dimension) of the electrode 3 in the direction perpendicular or substantially perpendicular to the length direction of the electrode 3 to the center of a dimension (width dimension) of the electrode 4 in the direction perpendicular or substantially perpendicular to the length direction of the electrode 4.

In the first preferred embodiment, a Z-cut piezoelectric layer is used, and thus, the direction perpendicular or substantially perpendicular to the length direction of the electrodes 3 and 4 is a direction perpendicular or substantially perpendicular to the polarization direction of the piezoelectric layer 2 unless a piezoelectric body having a different cut-angle is used as the piezoelectric layer 2. Here, the term “perpendicular” is not limited to referring to being exactly perpendicular and may refer to being substantially perpendicular (the angle formed by the direction perpendicular to the length direction of the electrodes 3 and 4 and the polarization direction is, for example, within a range of about 90°±10°).

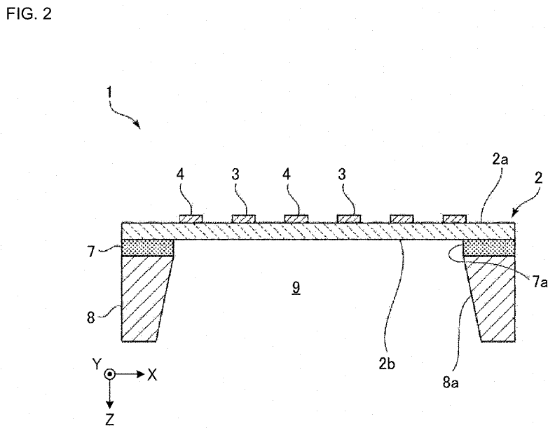

A support member 8 is stacked on the second main surface 2b of the piezoelectric layer 2 with an intermediate layer 7 interposed therebetween. The intermediate layer 7 and the support member 8 each have a frame shape, and as illustrated in FIG. 2, cavities 7a and 8a are respectively provided in the intermediate layer 7 and the support member 8. As a result, a hollow portion (an air gap) 9 is provided.

The hollow portion 9 is provided so as not to hinder vibration of an excitation region C of the piezoelectric layer 2. Thus, the support member 8 is stacked on the second main surface 2b with the intermediate layer 7 interposed therebetween and located at a position at which the support member 8 does not overlap a portion where at least one of the pairs of electrodes 3 and 4 are provided. The intermediate layer 7 does not need to be provided. Accordingly, the support member 8 may be stacked directly or indirectly on the second main surface 2b of the piezoelectric layer 2.

The intermediate layer 7 is an insulating layer and is made of, for example, a silicon oxide. However, the intermediate layer 7 may be made of a suitable insulating material such as, for example, silicon oxynitride or alumina other than a silicon oxide.

The support member 8 will also be referred to as a support substrate and is made of, for example, Si. The plane orientation of a surface of the Si, the surface facing the piezoelectric layer 2, may be (100) or (110) or may be (111). It is preferable that the Si has a high resistance, that is, a resistivity of, for example, about 4 kΩ or higher. The support member 8 may also be made of a suitable insulating material or a suitable semiconductor material, for example. Examples of the materials that can be used for the support member 8 include piezoelectric materials such as aluminum oxide, lithium tantalate, lithium niobate, and quartz crystal, various ceramic materials such as alumina, magnesia, sapphire, silicon nitride, aluminum nitride, silicon carbide, zirconia, cordierite, mullite, steatite, and forsterite, dielectric materials such as diamond and glass, and a semiconductor such as gallium nitride.

The plurality of electrodes 3 and 4 and the first and second busbars 5 and 6 are made of a suitable metal such as, for example, Al or a suitable alloy such as an AlCu alloy. In the first preferred embodiment, for example, the electrodes 3 and 4 and the first and second busbars 5 and 6 each have a structure in which an Al film is laminated on a Ti film. A close-contact layer that is not a Ti film may be used.

When the acoustic wave device 1 is driven, an alternating-current voltage is applied between the plurality of electrodes 3 and the plurality of electrodes 4. More specifically, the alternating-current voltage is applied between the first busbar 5 and the second busbar 6. As a result, resonance characteristics using a bulk wave in the thickness-shear primary mode that is excited in the piezoelectric layer 2 can be obtained.

In the acoustic wave device 1, when the thickness of the piezoelectric layer 2 is denoted by d and the center-to-center distance between the adjacent electrodes 3 and 4 forming one of the pairs of electrodes 3 and 4 is denoted by p, d/p is, for example, about 0.5 or less. Thus, the bulk wave in the thickness-shear primary mode is effectively excited, and favorable resonance characteristics can be obtained. More preferably, d/p is, for example, about 0.24 or less, and in this case, more favorable resonance characteristics can be obtained.

As in the first preferred embodiment, in the case where at least one of the number of the electrodes 3 and the number of the electrodes 4 is two or more, that is, when a single electrode 3 and a single electrode 4 define a pair of electrodes and the number of pairs of electrodes is 1.5 or more, a center-to-center distance p between the adjacent electrodes 3 and 4 is the average distance of the center-to-center distances between the adjacent electrodes 3 and 4.

Since the acoustic wave device 1 of the first preferred embodiment has the above-described configuration, the Q value is less likely to decrease even if the number of the pairs of electrodes 3 and 4 is reduced so as to facilitate a reduction in the size of the acoustic wave device 1. The reason is that a propagation loss is small because of a resonator that does not need reflectors on both sides. No reflectors are necessary because the bulk wave in the thickness-shear primary mode is used.

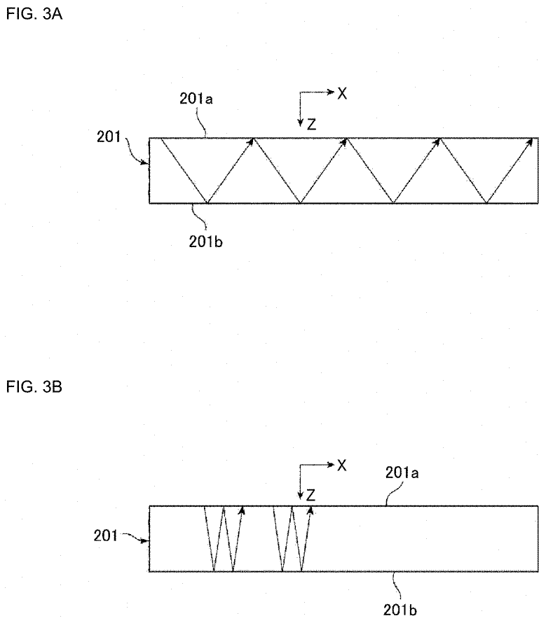

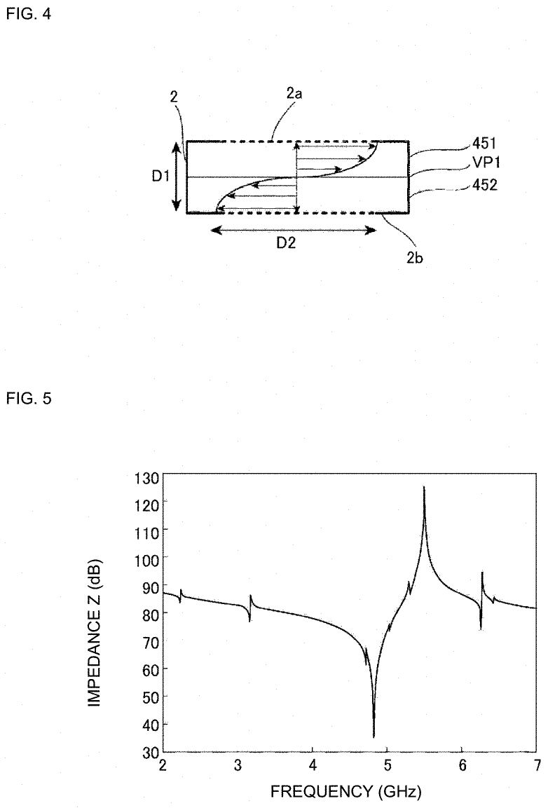

FIG. 3A is a schematic sectional view illustrating a Lamb wave propagating in a piezoelectric layer of a comparative example. FIG. 3B is a schematic sectional view illustrating a bulk wave in the thickness-shear primary mode propagating in the piezoelectric layer of the first preferred embodiment. FIG. 4 is a schematic sectional view illustrating an amplitude direction of the bulk wave in the thickness-shear primary mode propagating in the piezoelectric layer of the first preferred embodiment.

FIG. 3A illustrates an acoustic wave device such as that described in Japanese Unexamined Patent Application Publication No. 2012-257019, and a Lamb wave propagates in a piezoelectric layer. As illustrated in FIG. 3A, a wave propagates in a piezoelectric layer 201 as indicated by arrows. Here, the piezoelectric layer 201 includes a first main surface 201a and a second main surface 201b, and a thickness direction connecting the first main surface 201a and the second main surface 201b to each other is the Z direction. The X direction is a direction in which electrode fingers of an IDT electrode are arranged. In the case of a Lamb wave, the wave propagates in the X direction as illustrated in FIG. 3A. Although the entire piezoelectric layer 201 vibrates because the lamb wave is a type of plate waves, since the wave propagates in the X direction, reflectors are arranged on both sides so as to obtain resonance characteristics. Consequently, a propagation loss of the wave occurs, and if the size reduction is performed, that is, if the number of pairs of electrode fingers is reduced, the Q value decreases.

In contrast, as illustrated in FIG. 3B, in the acoustic wave device according to the first preferred embodiment, vibration displacement occurs in a thickness shear direction, and thus, the wave substantially propagates and resonates in a direction connecting the first main surface 2a and the second main surface 2b of the piezoelectric layer 2 to each other, that is, the Z direction. In other words, an X-direction component of the wave is considerably smaller than a Z-direction component of the wave. The resonance characteristics are obtained as a result of the wave propagating in the Z direction, and thus, it is not necessary to provide reflectors. Accordingly, there will be no propagation loss that is generated when the wave propagates to reflectors. Therefore, even if the number of pairs of electrodes 3 and 4 is reduced so as to facilitate the size reduction, the Q value is less likely to decrease.

As illustrated in FIG. 4, the amplitude direction of the bulk wave in the thickness-shear primary mode in a first region 451 that is included in the excitation region C (see FIG. 1B) of the piezoelectric layer 2 is opposite to the amplitude direction of the bulk wave in the thickness-shear primary mode in a second region 452 that is included in the excitation region C. FIG. 4 schematically illustrates a bulk wave in the case where a voltage is applied between the electrodes 3 and 4, the voltage causing the potential of the electrode 4 to become higher than that of the electrode 3. The first region 451 is a region included in the excitation region C and is a region between a virtual plane VP1 and the first main surface 2a, the virtual plane VP1 being perpendicular or substantially perpendicular to the thickness direction of the piezoelectric layer 2 and dividing the piezoelectric layer 2 into two portions. The second region 452 is a region included in the excitation region C and is a region between the virtual plane VP1 and the second main surface 2b.

In the acoustic wave device 1, although at least one pair of electrodes 3 and 4 are provided, it does not cause a wave to propagate in the X direction, and thus, the number of pairs of the electrodes 3 and 4 does not need to be two or more. In other words, it is only necessary that at least one pair of electrodes is provided.

For example, the electrodes 3 are electrodes connected to the hot potential, and the electrodes 4 are electrodes connected to the ground potential. However, the electrodes 3 may be connected to the ground potential, and the electrodes 4 may be connected to the hot potential. In the first preferred embodiment, at least one pair of electrodes are electrodes connected to the hot potential and the ground potential, and no floating electrode is provided.

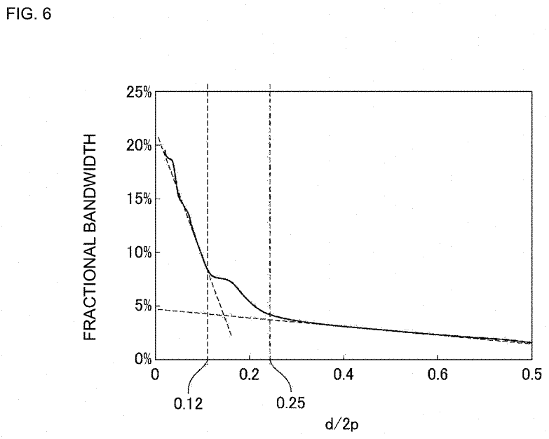

FIG. 5 is a graph illustrating exemplary resonance characteristics of the acoustic wave device according to the first preferred embodiment. The design parameters of the acoustic wave device 1 that have obtained the resonance characteristics illustrated in FIG. 5 are as follows.

Piezoelectric layer 2: LiNbO₃ with Euler angles of (0°, 0°, 90°)

Thickness of piezoelectric layer 2=about 400 nm

Length of excitation region C (see FIG. 1B): about 40 μm

Number of pairs of electrodes 3 and 4: 21 pairs

Center-to-center distance (pitch) between electrodes 3 and 4: about 3 μm

Width of each of electrodes 3 and 4: about 500 nm

d/p: about 0.133

Intermediate layer 7: silicon oxide film having a thickness of about 1 μm

Support member 8: Si

The excitation region C (see FIG. 1B) is a region in which one of the electrodes 3 and the corresponding electrode 4 overlap each other when viewed in the X direction perpendicular or substantially perpendicular to the length direction of the electrodes 3 and 4. The length of the excitation region C is a dimension of the excitation region C along the length direction of the electrodes 3 and 4.

In the first preferred embodiment, the electrode-to-electrode distances in the pairs of electrodes including the electrodes 3 and 4 were set to be the same or substantially the same as one another. In other words, the electrodes 3 and the electrodes 4 were arranged at the same or substantially the same pitch.

As is clear from FIG. 5, despite the fact that no reflectors are provided, a favorable resonance characteristic, which is a fractional bandwidth of about 12.5%, is obtained.

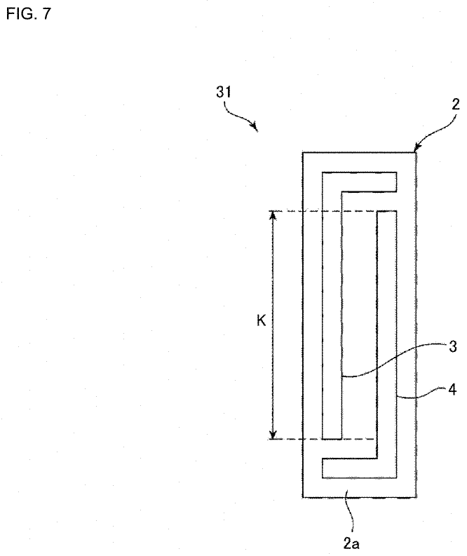

In the first preferred embodiment, preferably, d/p is about 0.5 or less and more preferably about 0.24 or less, where d is the thickness of the above-mentioned piezoelectric layer 2 and p is the center-to-center distance between each of the electrodes 3 and the corresponding electrode 4. This matter will now be described with reference to FIG. 6.

A plurality of acoustic wave devices were obtained in a manner the same as or similar to the acoustic wave device that has obtained the resonance characteristics illustrated in FIG. 5 except that d/2p was varied. FIG. 6 is a graph illustrating a relationship between d/2p and a fractional bandwidth as a resonator, where p is the center-to-center distance between adjacent electrodes in the acoustic wave device of the first preferred embodiment or the average distance of the center-to-center distances and d is the average thickness of the piezoelectric layer.

As illustrated in FIG. 6, when d/2p exceeds about 0.25, that is, d/p>about 0.5, the fractional bandwidth is less than about 5% even if d/p is adjusted. In contrast, in the case of d/2p about 0.25, that is, d/p about 0.5, the fractional bandwidth can be about 5% or more by changing d/p within the range. In other words, a resonator having a high coupling coefficient can be provided. In addition, when d/2p is about 0.12 or less, that is, d/p is about 0.24 or less, the fractional bandwidth can be improved to about 7% or more. Furthermore, by adjusting d/p within this range, a resonator having an even wider fractional bandwidth can be obtained, and a resonator having an even higher coupling coefficient can be achieved. Thus, it is understood that a resonator that uses the bulk wave in the thickness-shear primary mode and that has a high coupling coefficient can be provided by setting d/p to be about 0.5 or less.

At least one pair of electrodes may be a single pair of electrodes, and in this case, the p is the center-to-center distance between the adjacent electrodes 3 and 4. In addition, in the case where the number of pairs of electrodes is 1.5 or more, p may be the average distance of the center-to-center distances between the adjacent electrodes 3 and 4.

In addition, if the piezoelectric layer 2 has a non-uniform thickness, a value obtained by averaging the thicknesses may be used as the thickness d of the piezoelectric layer.

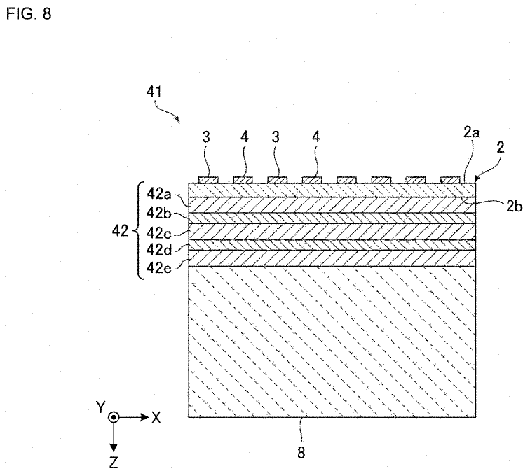

FIG. 7 is a plan view illustrating a case where a pair of electrodes are provided in the acoustic wave device according to the first preferred embodiment. In an acoustic wave device 31, a single pair of electrodes including one of the electrodes 3 and one of the electrodes 4 are provided on the first main surface 2a of the piezoelectric layer 2. An intersecting width is denoted by K in FIG. 7. As described above, in the acoustic wave device, the number of pairs of electrodes may be one. Also in this case, a bulk wave in the thickness-shear primary mode can be effectively excited as long as the d/p is, for example, about 0.5 or less.

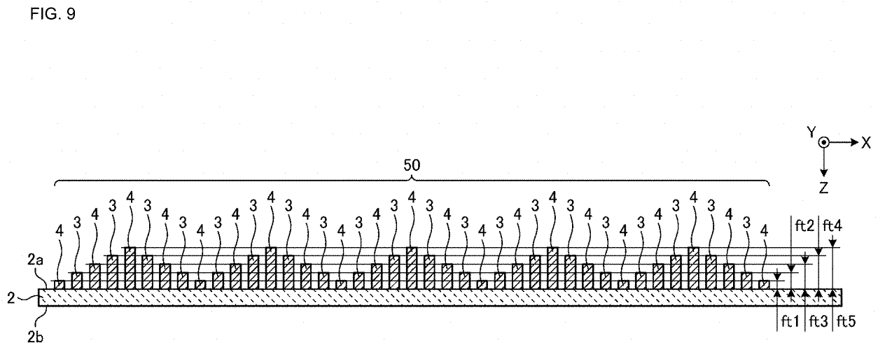

FIG. 8 is a sectional view of a portion of a modification of the first preferred embodiment taken along line II-II of FIG. 1A. In an acoustic wave device 41, an acoustic multilayer film 42 is laminated on the second main surface 2b of the piezoelectric layer 2. The acoustic multilayer film 42 has a multilayer structure including low-acoustic-impedance layers 42a, 42c, and 42e each having a relatively low acoustic impedance and high-acoustic-impedance layers 42b and 42d each having a relatively high acoustic impedance. By using the acoustic multilayer film 42, the bulk wave in the thickness-shear primary mode can be confined within the piezoelectric layer 2 without using the hollow portion 9 of the acoustic wave device 1. Also in the acoustic wave device 41, by setting the d/p to, for example, about 0.5 or less, resonance characteristics based on the bulk wave in the thickness-shear primary mode can be obtained. In the acoustic multilayer film 42, the number of the acoustic-impedance layers including the low-acoustic-impedance layers 42a, 42c, and 42e and the high-acoustic-impedance layers 42b and 42d laminated together is not particularly limited as long as at least one of the high-acoustic-impedance layers 42b and 42d is positioned farther from the piezoelectric layer 2 than each of the low-acoustic-impedance layers 42a, 42c, and 42e is.

The low-acoustic-impedance layers 42a, 42c, and 42e and the high-acoustic-impedance layers 42b and 42d can be made of a suitable material as long as they satisfy the above-described relationship. Examples of the material of the low-acoustic-impedance layers 42a, 42c, and 42e include a silicon oxide and silicon oxynitride. Examples of the material of the high-acoustic-impedance layers 42b and 42d include alumina, silicon nitride, and a metal.

As described above, in the acoustic wave devices 1, 31, and 41, the bulk wave in the thickness-shear primary mode is used. In addition, in the acoustic wave devices 1, 31, and 41, each of the first electrodes 3 is adjacent to one of the second electrodes 4, and d/p is about 0.5 or less, where d is the thickness of the piezoelectric layer and p is the center-to-center distance between each of the first electrodes and the adjacent second electrode. As a result, the Q value can be improved even if the acoustic wave device is reduced in size.

In the acoustic wave devices 1, 31, and 41, the piezoelectric layer 2 is made of, for example, lithium niobate or lithium tantalate. The first electrodes 3 and the second electrodes 4 are provided on the first main surface 2a or the second main surface 2b of the piezoelectric layer 2 so as to face one another in a direction crossing the thickness direction of the piezoelectric layer 2, and it is preferable that a protective film cover the first electrodes 3 and the second electrodes 4 from above.

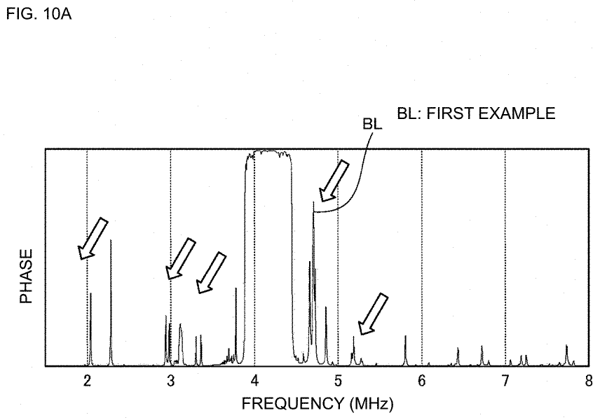

FIG. 9 is a sectional view taken along line IX-IX of FIG. 1B in the first preferred embodiment. For ease of understanding, the film thicknesses of the electrodes 3 and 4 are exaggeratedly illustrated in FIG. 9 compared with the actual differences between the film thicknesses. In the first preferred embodiment, the film thicknesses of the electrodes 3 and 4 illustrated in FIG. 2 are each one of a film thickness ft1, a film thickness ft2, a film thickness ft3, a film thickness ft4, and a film thickness ft5 as illustrated in FIG. 9. In the following description, when there is no need to distinguish the electrodes 3 and 4 from each other, they will be referred to as electrodes 50. The difference between the film thickness ft1 and the film thickness ft2 is, for example, about 10 nm. The difference between the film thickness ft2 and the film thickness ft3 is, for example, about 10 nm. The difference between the film thickness ft3 and the film thickness ft4 is, for example, about 10 nm. The difference between the film thickness ft4 and the film thickness ft5 is, for example, about 10 nm. When the film thickness ft1 is, for example, about 580 nm, the film thickness ft2, the film thickness ft3, the film thickness ft4, and the film thickness ft5 are, for example, about 590 nm, about 600 nm, about 610 nm, and about 620 nm, respectively.

The number of the electrodes 50 that are sandwiched in the X direction between the two electrodes 50 each having the film thickness ft1 is seven. The number of the electrodes 50 that are sandwiched in the X direction between the two electrodes 50 each having the film thickness ft2 is seven. The number of the electrodes 50 that are sandwiched in the X direction between the two electrodes 50 each having the film thickness ft3 is seven. The number of the electrodes 50 that are sandwiched in the X direction between the two electrodes 50 each having the film thickness ft4 is seven. The number of the electrodes 50 that are sandwiched in the X direction between the two electrodes 50 each having the film thickness ft5 is seven. In this manner, in the electrodes 50 arranged in the X direction, each pair of the electrodes 50 having the same or substantially the same film thickness sandwich the same number of the electrodes 50 each of which has a film thickness different from that of the pair of electrodes 50. When two of the electrodes 50 have the same or substantially the same film thickness, the film thickness of one of the two electrodes 50 may be within a range of, for example, about ±5% of the film thickness of the other electrode 50.

The electrodes 50 are arranged in the X direction in a combination of film thicknesses which is the film thickness ft1, the film thickness ft2, the film thickness ft3, the film thickness ft4, the film thickness ft5, the film thickness ft4, the film thickness ft3, the film thickness ft2, and the film thickness ft1 in this order in the X direction. This combination of film thicknesses is repeated in the X direction. In this manner, there is regularity in the combination of the film thicknesses of the electrodes 50 arranged in the X direction. For example, the electrodes 50 each having the film thickness ft1 are arranged regularly in such a manner that every eighth electrode 50 in the X direction is the electrode 50 having the film thickness ft1.

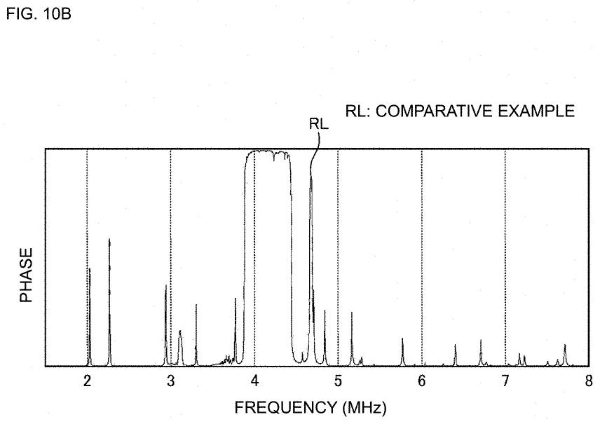

FIG. 10A is a graph illustrating a relationship between spurious and frequency according to the first preferred embodiment. The simulation conditions of a first example BL of the first preferred embodiment are as follows, and FIG. 10A illustrates evaluation results.

Center-to-center distance (pitch) between electrodes 3 and 4: about 4.2 μm

Piezoelectric layer 2: LiNbO₃ with Euler angles of (0°, 127.5°, 0°)

Film thickness of piezoelectric layer: about 0.5 μm

Material of electrodes 3 and 4: Al

Center-to-center distance (pitch) between electrodes 3 and 4: about 3.14 μm

Electrode line width of each of electrodes 3 and 4: about 1.26 μm

Gap width between first busbar and each electrode 4 and gap width between second busbar and each electrode 3: about 1.90 μm

Number of pairs of electrodes: 20 pairs (41 electrodes) Film thicknesses of electrodes 3 and 4: When the film thickness ft1 is about 580 nm, the film thickness ft2, the film thickness ft3, the film thickness ft4, and the film thickness ft5 are about 590 nm, about 600 nm, about 610 nm, and about 620 nm, respectively. The electrodes 3 and 4 are arranged in the combination of film thicknesses illustrated in FIG. 9.

FIG. 10B is a graph illustrating a relationship between spurious and frequency in a comparative example.

The simulation conditions of a comparative example RL are as follows, and FIG. 10B illustrates evaluation results.

Center-to-center distance (pitch) between electrodes 3 and 4: about 4.2 μm

Piezoelectric layer 2: LiNbO₃ with Euler angles of (0°, 127.5°, 0°)

Film thickness of piezoelectric layer: about 0.5 μm

Material of electrodes 3 and 4: Al

Center-to-center distance (pitch) between electrodes 3 and 4: about 3.14 μm

Electrode line width of each of electrodes 3 and 4: about 1.26 μm

Gap width between first busbar and each electrode 4 and gap width between second busbar and each electrode 3: about 1.90 μm

Number of pairs of electrodes: 20 pairs (41 electrodes)

Film thickness of each of electrodes 3 and 4: about 600 nm

FIGS. 10A and 10B illustrate resonance characteristics, and the horizontal axis and the vertical axis denote frequency and phase, respectively. By referring to the frequencies in FIG. 10A the same as those in FIG. 10B at which spurious in the comparative example RL appeared, it is understood that the intensity of spurious at each of the positions indicated by arrows is suppressed.

### Second Preferred Embodiment

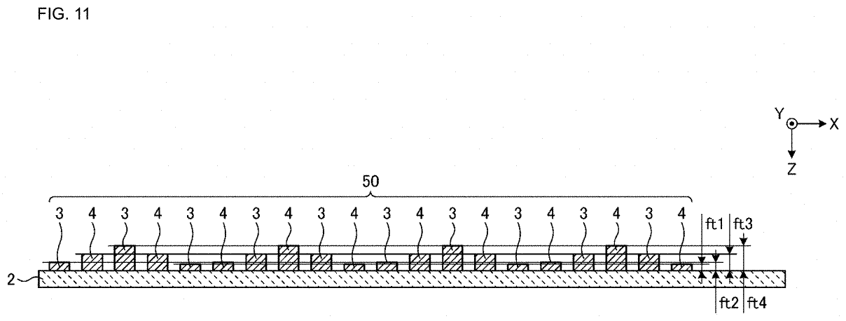

FIG. 11 is a sectional view of a portion according to a second preferred embodiment of the present invention taken along line IX-IX of FIG. 1B. For ease of understanding, the film thicknesses of the electrodes 3 and 4 are exaggeratedly illustrated in FIG. 11 compared with the actual differences between the film thicknesses. In the second preferred embodiment, the film thicknesses of the electrodes 3 and 4 illustrated in FIG. 11 are each one of the film thickness ft1, the film thickness ft2, the film thickness ft3, and the film thickness ft4.

The film thicknesses of the electrodes 3 and 4 satisfy a relationship of ft1<ft2<ft3<ft4. The film thickness difference between the film thickness ft1 and the film thickness ft2 is smaller than the film thickness difference between the film thickness ft2 and the film thickness ft3. In the second preferred embodiment, the film thickness difference varies among the pairs of adjacent electrodes 3 and 4. In addition, the film thicknesses of each three electrodes 3, 4, and 3 arranged next to one another in the X direction are different from one another.

The number of the electrodes 50 that are sandwiched in the X direction between the two electrodes 50 each having the film thickness ft1 is four. The number of the electrodes 50 that are sandwiched in the X direction between the two electrodes 50 each having the film thickness ft2 is four. The number of the electrodes 50 that are sandwiched in the X direction between the two electrodes 50 each having the film thickness ft3 is one or four. The number of the electrodes 50 that are sandwiched in the X direction between the two electrodes 50 each having the film thickness ft4 is four. In this manner, in the electrodes 50 arranged in the X direction, there is regularity in the number of the electrodes 50 that are sandwiched between each pair of the electrodes 50 having the same or substantially the same film thickness and each of which has a film thickness different from that of the pair of electrodes 50. Note that, when two of the electrodes 50 have the same or substantially the same film thickness, the film thickness of one of the two electrodes 50 may be within a range of about ±5% of the film thickness of the other electrode 50.

The electrodes 50 are arranged in the X direction in a combination of film thicknesses which is the film thickness ft1, the film thickness ft2, the film thickness ft3, the film thickness ft4, the film thickness ft3, and the film thickness ft1 in this order in the X direction. This combination of film thicknesses is repeated in the X direction. In this manner, there is regularity in the combination of the film thicknesses of the electrodes 50 arranged in the X direction. For example, the electrodes 50 each having the film thickness ft1 are arranged regularly in such a manner that every fifth electrode 50 in the X direction is the electrode 50 having the film thickness ft1.

### Third Preferred Embodiment

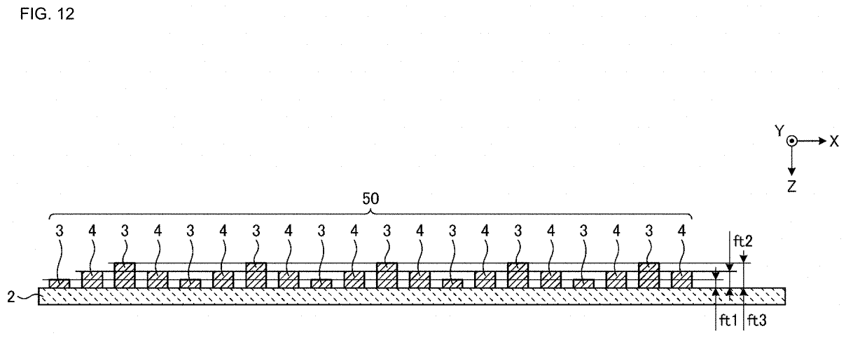

FIG. 12 is a sectional view of a portion according to a third preferred embodiment of the present invention taken along line IX-IX of FIG. 1B. For ease of understanding, the film thicknesses of the electrodes 3 and 4 are exaggeratedly illustrated in FIG. 12 compared with the actual differences between the film thicknesses. In the third preferred embodiment, the film thicknesses of the electrodes 3 and 4 illustrated in FIG. 12 are each one of the film thickness ft1, the film thickness ft2, and the film thickness ft3.

The film thicknesses of the electrodes 3 and 4 satisfy a relationship of ft1<ft2<ft3. The film thickness difference between the film thickness ft1 and the film thickness ft2 is the same or substantially the same as the film thickness difference between the film thickness ft2 and the film thickness ft3. In the third preferred embodiment, the pairs of adjacent electrodes 3 and 4 have the same or substantially the same film thickness difference. In addition, the film thicknesses of each three electrodes 3, 4, and 3 arranged next to one another in the X direction are different from one another.

The number of the electrodes 50 that are sandwiched in the X direction between the two electrodes 50 each having the film thickness ft1 is three. The number of the electrodes 50 that are sandwiched in the X direction between the two electrodes 50 each having the film thickness ft2 is three. The number of the electrodes 50 that are sandwiched in the X direction between the two electrodes 50 each having the film thickness ft3 is three. In this manner, in the electrodes 50 arranged in the X direction, each pair of the electrodes 50 having the same or substantially the same film thickness sandwich the same number of the electrodes 50 each of which has a film thickness different from that of the pair of electrodes 50. Note that, when two of the electrodes 50 have the same or substantially the same film thickness, the film thickness of one of the two electrodes 50 may be within a range of about ±5% of the film thickness of the other electrode 50.

The electrodes 50 are arranged in the X direction in a combination of film thicknesses which is the film thickness ft1, the film thickness ft2, the film thickness ft3, the film thickness ft2, and the film thickness ft1 in this order in the X direction. This combination of film thicknesses is repeated in the X direction. In this manner, there is regularity in the combination of the film thicknesses of the electrodes 50 arranged in the X direction. For example, the electrodes 50 each having the film thickness ft1 are arranged regularly in such a manner that every fourth electrode 50 in the X direction is the electrode 50 having the film thickness ft1.

### Fourth Preferred Embodiment

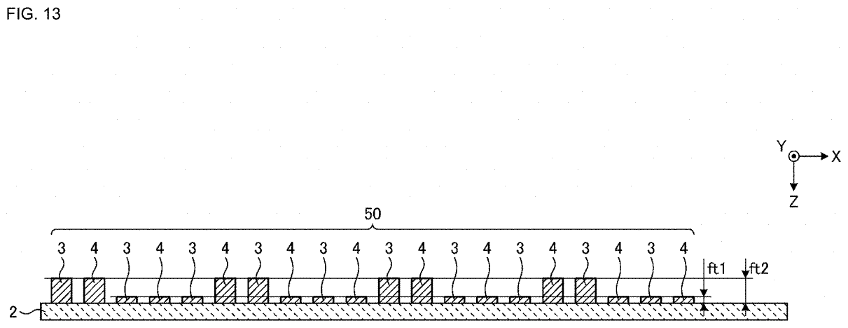

FIG. 13 is a sectional view of a portion according to a fourth preferred embodiment of the present invention taken along line IX-IX of FIG. 1B. For ease of understanding, the film thicknesses of the electrodes 3 and 4 are exaggeratedly illustrated in FIG. 13 compared with the actual differences between the film thicknesses. In the fourth preferred embodiment, the film thicknesses of the electrodes 3 and 4 illustrated in FIG. 13 are each the film thickness ft1 or the film thickness ft2.

The film thicknesses of the electrodes 3 and 4 satisfy a relationship of ft1<ft2. The acoustic wave device of the fourth preferred embodiment includes at least two electrodes 50 having different film thicknesses from each other and has a region in which the electrodes 50 that are adjacent to each other in the X direction have the same or substantially the same film thickness. Note that, when the adjacent electrodes 3 and 4 have the same or substantially the same film thickness, the film thickness of one of the adjacent electrodes, which is the electrode 3, may be within a range of about ±5% of the film thickness of the other electrode, which is the electrode 4.

The plurality of electrodes 50 are arranged in the X direction in a combination of film thicknesses with which two electrodes 50 each having the film thickness ft2 are arranged next to each other in the X direction and with which three electrodes 50 each having the film thickness ft1 are arranged next to one another in the X direction. This combination of film thicknesses is repeated in the X direction. In this manner, there is regularity in the combination of the film thicknesses of the electrodes 50 arranged in the X direction.

### Fifth Preferred Embodiment

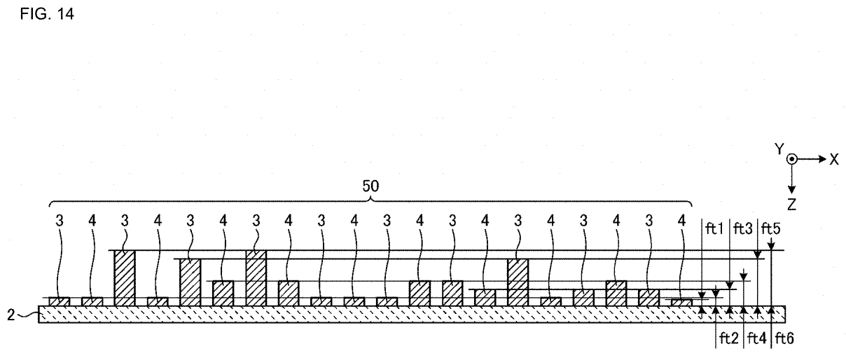

FIG. 14 is a sectional view of a portion according to a fifth preferred embodiment of the present invention taken along line IX-IX of FIG. 1B. For ease of understanding, the film thicknesses of the electrodes 3 and 4 are exaggeratedly illustrated in FIG. 14 compared with the actual differences between the film thicknesses. In the fifth preferred embodiment, the film thicknesses of the electrodes 3 and 4 illustrated in FIG. 13 are each one of the film thickness ft1, the film thickness ft2, the film thickness ft3, the film thickness ft4, the film thickness ft5, and a film thickness ft6.

The film thicknesses of the electrodes 3 and 4 satisfy a relationship of ft1<ft2<ft3<ft4<ft5<ft6. The film thickness difference between the film thickness ft1 and the film thickness ft2 is smaller than the film thickness difference between the film thickness ft2 and the film thickness ft3. In the fifth preferred embodiment, there is a region in which the film thickness difference varies among the pairs of adjacent electrodes 3 and 4.

The acoustic wave device of the fifth preferred embodiment includes at least six electrodes 50 having different film thicknesses from one another and includes a region in which the electrodes 50 that are adjacent to each other in the X direction both have the film thickness ft1. When the adjacent electrodes 3 and 4 have the same or substantially the same film thickness, the film thickness of one of the adjacent electrodes, which is the electrode 3, may be within a range of about ±5% of the film thickness of the other electrode, which is the electrode 4.

The acoustic wave device of the fifth preferred embodiment includes a region in which at least three electrodes 50 having different film thicknesses from one another are arranged next to one another in the X direction. The film thicknesses of the electrodes 50 arranged in the X direction are set in a random manner. Accordingly, there is no regularity in the film thicknesses of the electrodes 50 arranged in the X direction.

### Sixth Preferred Embodiment

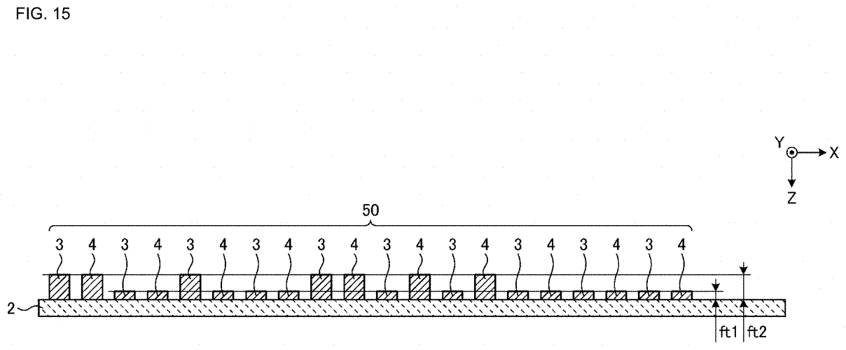

FIG. 15 is a sectional view of a portion according to a sixth preferred embodiment of the present invention taken along line IX-IX of FIG. 1B. For ease of understanding, the film thicknesses of the electrodes 3 and 4 are exaggeratedly illustrated in FIG. 15 compared with the actual differences between the film thicknesses. In the sixth preferred embodiment, the film thicknesses of the electrodes 3 and 4 illustrated in FIG. 15 are each the film thickness ft1 or the film thickness ft2.

The film thicknesses of the electrodes 3 and 4 satisfy a relationship of ft1<ft2. The acoustic wave device of the sixth preferred embodiment includes at least two electrodes 50 having different film thicknesses from each other and includes a region in which the electrodes 50 that are adjacent to each other in the X direction have the same or substantially the same film thickness. When the adjacent electrodes 3 and 4 have the same or substantially the same film thickness, the film thickness of one of the adjacent electrodes, which is the electrode 3, may be within a range of abut ±5% of the film thickness of the other electrode, which is the electrode 4.

The plurality of electrodes 50 are arranged in the X direction in a combination of film thicknesses with which two electrodes 50 each having the film thickness ft1 are arranged next to each other in the X direction and with which three electrodes 50 each having the film thickness ft1 are arranged next to one another in the X direction. This combination of film thicknesses is repeated in the X direction. In this manner, there is regularity in the combination of the film thicknesses of the electrodes 50 arranged in the X direction.

The acoustic wave device of the sixth preferred embodiment includes a region in which at least two electrodes 50 having different film thicknesses from each other are arranged next to each other in the X direction. The film thicknesses of the electrodes 50 arranged in the X direction are set in a random manner. Accordingly, there is no regularity in the film thicknesses of the electrodes 50 arranged in the X direction.

As described above, the acoustic wave device includes the piezoelectric layer 2 including the first main surface 2a and the second main surface 2b, the second main surface 2b being opposite to the first main surface 2a and being located in the Z direction from the first main surface 2a, and the plurality of electrodes 50 including at least a pair of electrodes 3 and 4 that are arranged on the first main surface 2a so as to face each other in the X direction crossing the Z direction and be adjacent to each other.

As in the first preferred embodiment, the second preferred embodiment, the third preferred embodiment, and the fifth preferred embodiment, at least three or more of the plurality of electrodes 50 are arranged in the X direction, and the plurality of electrodes 50 include at least three electrodes having different film thicknesses from one another.

As a result, the resonant frequency and the anti-resonant frequency are less likely to be affected even when the electrodes 50 have different film thicknesses from one another. On the other hand, when the electrodes 50 have different film thicknesses from one another, spurious responses are reduced, and deterioration of the resonance characteristics can be reduced or prevented.

At least three of the electrodes 3 having different film thicknesses from one another have the same polarity. At least three of the electrodes 4 having different film thicknesses from one another have the same polarity. As a result, spurious responses are reduced, and deterioration of the resonance characteristics can be suppressed.

As in the fourth preferred embodiment and the sixth preferred embodiment, at least three or more of the plurality of electrodes 50 are arranged in the X direction, and the plurality of electrodes 50 include at least two electrodes having different film thicknesses from each other. The plurality of electrodes 50 at least include two electrodes 50 that have the same film thickness and that are adjacent to each other. As in the fifth preferred embodiment, the plurality of electrodes 50 may at least include two electrodes 50 that have the same film thickness and that are adjacent to each other.

As a result, the resonant frequency and the anti-resonant frequency are less likely to be affected even when the electrodes 50 have different film thicknesses from one another. On the other hand, when the electrodes 50 have different film thicknesses from one another, spurious responses are reduced, and deterioration of the resonance characteristics can be reduced or prevented.

At least two of the electrodes 3 having different film thicknesses from each other have the same polarity. At least two of the electrodes 4 having different film thicknesses from each other have the same polarity. As a result, spurious responses are reduced, and deterioration of the resonance characteristics can be reduced or prevented.

In each of the acoustic wave devices 1, 31, and 41, the bulk wave in the thickness-shear primary mode is used. As a result, the coupling coefficient is improved, and an acoustic wave device capable of obtaining favorable resonance characteristics can be provided.

The first electrodes 3 and the second electrodes 4 are the electrodes 50 that are adjacent to one another, and d/p is set to, for example, about 0.5 or less, where d is the thickness of the piezoelectric layer and p is the center-to-center distance between each of the first electrodes and the adjacent second electrode. As a result, the acoustic wave device can be reduced in size, and the Q value can be improved.

As a preferable aspect, there is regularity in the film thicknesses of the electrodes 50 arranged in the X direction. Consequently, by varying the regularity, it becomes easier to shift the frequency of particular spurious or to change the intensity of particular spurious.

As a preferable aspect, in the X direction, each pair of the electrodes 50 having the same or substantially the same film thickness sandwich the same number of electrodes 50 each of which has a film thickness different from the film thickness of the pair of electrodes 50. Consequently, by varying the number of the electrodes 50 that are sandwiched in the X direction between each pair of the electrodes 50 having the same or substantially the same film thickness, it becomes easier to shift the frequency of particular spurious or to change the intensity of particular spurious responses.

As a preferable aspect, there is no regularity in the film thicknesses of the electrodes 50 arranged in the X direction. As a result, occurrence of large spurious responses at a particular frequency can be reduced or prevented.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface, the second main surface being opposed to the first main surface and located in a first direction from the first main surface; and
a plurality of electrodes including at least a pair of electrodes on the first main surface, facing each other in a second direction crossing the first direction, and adjacent to each other; wherein
at least three or more of the plurality of electrodes are arranged in the second direction;
the plurality of electrodes include at least two electrodes having different film thicknesses from each other; and
the plurality of electrodes include at least two electrodes having a same or substantially a same film thickness and being adjacent to each other.

2. The acoustic wave device according to claim 1, wherein the at least two electrodes having different film thicknesses from each other have a same polarity.

3. An acoustic wave device comprising:
a piezoelectric layer including a first main surface and a second main surface, the second main surface being opposed to the first main surface and located in a first direction from the first main surface; and
a plurality of electrodes including at least a pair of electrodes on the first main surface, facing each other in a second direction crossing the first direction, and adjacent to each other; wherein
at least three or more of the plurality of electrodes are arranged in the second direction; and
the plurality of electrodes include at least three electrodes having different film thicknesses from one another.

4. The acoustic wave device according to claim 2, wherein the at least three electrodes having different film thicknesses from one another have a same polarity.

5. The acoustic wave device according to claim 3, wherein the plurality of electrodes include at least two electrodes having a same or substantially a same film thickness and being adjacent to each other.

6. The acoustic wave device according to claim 1, wherein
the piezoelectric layer includes lithium niobate or lithium tantalate; and
a bulk wave in a thickness-shear primary mode is used.

7. The acoustic wave device according to claim 1, wherein
the piezoelectric layer includes lithium niobate or lithium tantalate; and
d/p is about 0.5 or less, where d is an average thickness of the piezoelectric layer and p is a center-to-center distance between adjacent electrodes.

8. The acoustic wave device according to claim 1, wherein film thicknesses of the electrodes arranged in the second direction have regular or substantially regular film thicknesses.

9. The acoustic wave device according to claim 1, wherein, in the second direction, each pair of electrodes having a same or substantially a same film thickness sandwich a same number of electrodes each of which has a film thickness different from the film thickness of the pair of electrodes.

10. The acoustic wave device according to claim 1, wherein the electrodes arranged in the second direction have no regular or substantially regular film thickness.

11. The acoustic wave device according to claim 3, wherein
the piezoelectric layer includes lithium niobate or lithium tantalate; and
a bulk wave in a thickness-shear primary mode is used.

12. The acoustic wave device according to claim 3, wherein
the piezoelectric layer includes lithium niobate or lithium tantalate; and
d/p is about 0.5 or less, where d is an average thickness of the piezoelectric layer and p is a center-to-center distance between adjacent electrodes.

13. The acoustic wave device according to claim 3, wherein thicknesses of the electrodes arranged in the second direction have regular or substantially regular film thicknesses.

14. The acoustic wave device according to claim 3, wherein, in the second direction, each pair of electrodes having a same or substantially a same film thickness sandwich a same number of electrodes each of which has a film thickness different from the film thickness of the pair of electrodes.

15. The acoustic wave device according to claim 3, wherein the electrodes arranged in the second direction have no regular or substantially regular film thickness.

16. The acoustic wave device according to claim 1, wherein
the piezoelectric layer includes lithium niobate or lithium tantalate; and
d/p is about 0.24 or less, where d is an average thickness of the piezoelectric layer and p is a center-to-center distance between adjacent electrodes.

17. The acoustic wave device according to claim 3, wherein
the piezoelectric layer includes lithium niobate or lithium tantalate; and
d/p is about 0.24 or less, where d is an average thickness of the piezoelectric layer and p is a center-to-center distance between adjacent electrodes.

18. The acoustic wave device according to claim 1, wherein each of the plurality of electrodes has a rectangular or substantially rectangular shape.

19. The acoustic wave device according to claim 3, wherein each of the plurality of electrodes has a rectangular or substantially rectangular shape.
